(19) United States
(12) Patent Application Publication
(10) Pub. No.: US 2012/0119386 A1
(43) Pub. Date: May 17, 2012

(54) SEMICONDUCTOR DEVICE AND METHOD OF MANUFACTURING THE SAME

(76) Inventors: Yohei ITO, Yokohama-shi (JP); Junichi IDE, Saitama-shi (JP); Yasushi ITABASHI, Tokyo (JP)

(21) Appl. No.: 13/234,407

(22) Filed: Sep. 16, 2011

(30) Foreign Application Priority Data
Sep. 21, 2010 (JP) 2010-211377

(51) Int. Cl. H01L 23/522; H01L 21/78

(52) U.S. Cl. 257/777; 438/113; 257/E23.142; 257/E21.599

(57) ABSTRACT

According to one embodiment, a semiconductor device includes a semiconductor substrate which includes a first chip area and a second chip area. An insulation film is formed over the substrate. An electrical circuit is formed in the first chip area and is electrically independent from any component in another chip area. The electrical circuit includes an electrical element and an interconnect on the substrate and in the insulation film. Boundary patterns are formed in the insulation film between the first and second chip areas, are electrically independent from the electrical circuit, and have a gap therebetween. One of the boundary patterns surrounds the first chip area.

### CROSS-REFERENCE TO RELATED APPLICATIONS

This application is based upon and claims the benefit of priority from prior Japanese Patent Application No. 2010-211377, filed Sep. 21, 2010, the entire contents of which are incorporated herein by reference.

### FIELD

Embodiments described herein relate generally to a semiconductor device and a method of manufacturing the same.

### BACKGROUND

In order to manufacture semiconductor chips, semiconductor chips are formed on a substrate through a common process, and then they are divided. Such a dividing step is called dicing, for example. A boundary area is provided between chips and is called a dicing line, or a dicing area, for example. The dicing lines generally include no components formed therein. The dicing involves irradiation of the dicing line with a laser beam to cause damage, i.e., faults, in the dicing line in the substrate, on which target patterns are generally formed as marks for correct alignment of the laser. The damage caused by the irradiation of the laser deteriorates the mechanical strength of the substrate in the dicing line. Mechanical stress is then applied to the substrate to produce a crack that originates at the laser cut faults, which allows for chips to be divided.

In order to satisfy the need to manufacture more chips from a substrate, a size of a dicing line is continuously being required to be made smaller. However, decreasing the dicing line size makes it more difficult to control the dicing.

### BRIEF DESCRIPTION OF THE DRAWINGS

FIGS. 1A and 1B are a plan view and a sectional view of a semiconductor device of a first embodiment prior to laser cutting, respectively;

FIG. 2 is a sectional view illustrating a step of a manufacturing method of the semiconductor device of the first embodiment;

FIG. 3 is a sectional view illustrating a step subsequent to FIG. 2;

FIG. 4 is a sectional view illustrating a step subsequent to FIG. 3;

FIG. 5 is a sectional view illustrating a step subsequent to FIG. 4;

FIG. 6 is a sectional view illustrating a step subsequent to FIG. 5;

FIG. 7 is a sectional view illustrating a step subsequent to FIG. 6;

FIGS. 8A and 8B are a plan view and a sectional view of the semiconductor device during the laser cutting, respectively;

FIGS. 9A and 9B are a plan view and a sectional view of the semiconductor device during breaking;

FIG. 10 is a sectional view of a semiconductor device of a second embodiment prior to laser cutting;

FIG. 11 is a sectional view illustrating a step of a manufacturing method of the semiconductor device of the second embodiment;

FIG. 12 is a sectional view illustrating a step subsequent to FIG. 11;

FIG. 13 is a sectional view illustrating a step subsequent to FIG. 12;

FIG. 14 is a sectional view of a semiconductor device of a third embodiment prior to laser cutting;

FIG. 15 is a sectional view illustrating a step of a manufacturing method of the semiconductor device of the third embodiment;

FIG. 16 is a sectional view illustrating a step subsequent to FIG. 15;

FIG. 17 is a sectional view illustrating a step subsequent to FIG. 16;

FIG. 18 is a sectional view illustrating a step subsequent to FIG. 17;

FIG. 19 is a sectional view illustrating a step subsequent to FIG. 18;

FIG. 20 is a sectional view illustrating a step of a manufacturing method of a semiconductor device of a fourth embodiment;

FIG. 21 is a sectional view illustrating a step subsequent to FIG. 20;

FIG. 22 is a sectional view illustrating a step of a manufacturing method of a semiconductor device of a fifth embodiment;

FIG. 23 is a sectional view illustrating a step subsequent to FIG. 22; and

FIG. 24 is a sectional view illustrating conventional laser dicing.

### DETAILED DESCRIPTION

In general, according to one embodiment, a semiconductor device includes a semiconductor substrate which includes a first chip area and a second chip area. An insulation film is formed over the substrate. An electrical circuit is formed in the first chip area and is electrically independent from any component in another chip area. The electrical circuit includes an electrical element and an interconnect on the substrate and in the insulation film. Boundary patterns are formed in the insulation film between the first and second chip areas, are electrically independent from the electrical circuit, and have a gap therebetween. One of the boundary patterns surrounds the first chip area.

Embodiments of the present invention will now be described with reference to the drawings. In the following, the same components are indicated with the same reference numbers throughout the figures, and repetitive description will be given only when required. Note that the drawings are merely illustrative and a ratio of the relation between a thickness and a plane size and thicknesses among layers differs from an actual one. Therefore, a specific thickness and size should be determined in light of the following description. Moreover, the drawings naturally include portions which differ in size or a size relative to another portion among drawings.

### First Embodiment

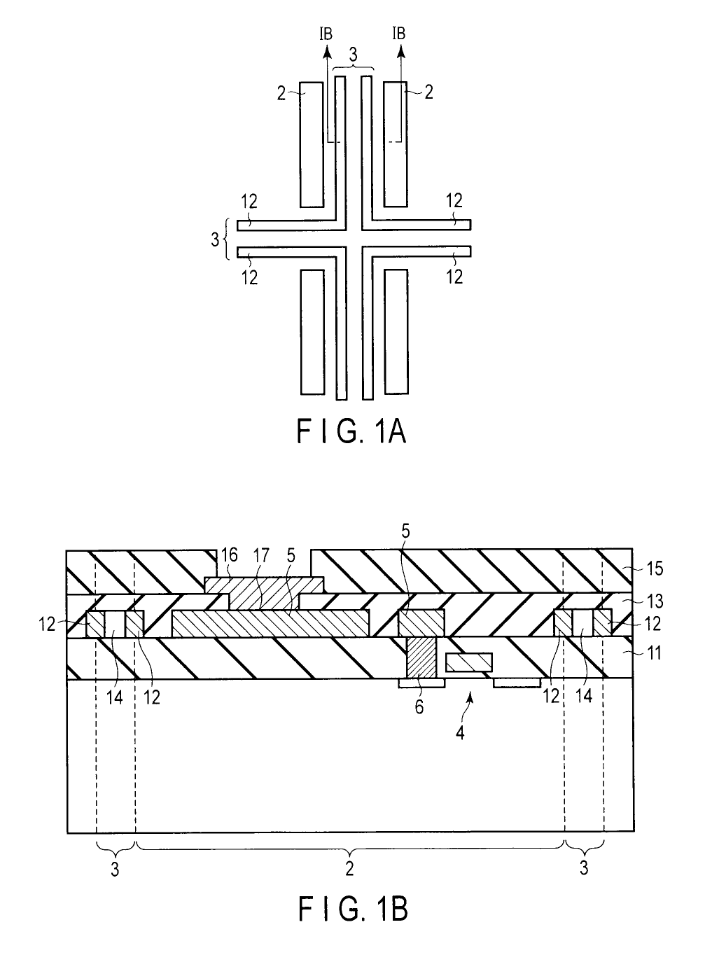

FIGS. 1 to 9 illustrate steps of a manufacturing method of a semiconductor device of a first embodiment. FIGS. 1A and 1B illustrate a semiconductor device prior to laser cutting. FIG. 1A is a plan view of the semiconductor substrate, and FIG. 1B a sectional view taken along IB-IB line in FIG. 1A. Steps for producing the structure of FIGS. 1A and 1B are described in detail later.

As shown in FIGS. 1A and 1B, in a silicon substrate 1 are formed a number of chip areas 2. Each chip area 2 is surrounded by a dicing line 3, and the chip areas 2 are separated by a dicing line 3 from each other. The chip areas 2 include electrical components therein. In particular, on the surface of the substrate 1 and in the area near the surface, transistors 4 are provided, for example. Conductive interconnects 5 and conductive contact plugs 6 are provided above the substrate 1 in the chip areas 2. One transistor 4 and one plug 6 are only illustrated in the figures for the purpose of clarification. The transistors 4, interconnects 5, and plugs 6 are connected to each other in various forms to form desired circuits. The circuits formed in the chip areas 2 include solid state imaging devices, for example.

The upper surface of the substrate 1 is covered with an inter-layer film 11 of an insulation material. A specific material of the inter-layer film 11 is known for a person skilled in the art. The interconnect 5 is located on the inter-layer film 11, and the plug 6 extends through the inter-layer film 11 and electrically connects a source/drain area of the transistor 4 and the interconnect 5.

A pair of boundary patterns 12 is provided on the inter-layer film 11 in each dicing line 3. The boundary patterns 12 comprise the same layer as the interconnect 5, and are patterned by the same process as the interconnect 5. For this reason, the boundary patterns 12 are typically flush with the interconnect 5. The plane shapes (the shape along the surface of the substrate 1) of the boundary patterns 12 extend along the both ends of each dicing line 3. The boundary patterns 12 make no contribution to transmission of electrical signals, and therefore are electrically independent from any components. The boundary patterns 12 may also be formed from a material different from the interconnect 5.

The upper surface of the inter-layer film 11 is covered with an inter-layer film 13 of an insulation material. A specific material of the inter-layer film 13 is known for a person skilled in the art. Between each pair of boundary patterns 12 extending along the both ends of each dicing line 3, the inter-layer film 13 is not buried and there are voids. One boundary pattern 12 surrounds one chip area 2, and a slit 14 is formed between boundary patterns 12 in each dicing line 3 as shown in FIG. 1A.

The entire surface of the inter-layer film 13 is covered with a passivation film 15 of an insulation material. A specific material of the passivation film 15 is known for a person skilled in the art. In the passivation film 15, a pad 16 of a conductive material is formed. The passivation film 15 has an opening which reaches the pad 16. In the inter-layer film 13, a plug 17 is provided. The plug 17 connects the pad 16 and the interconnect 5.

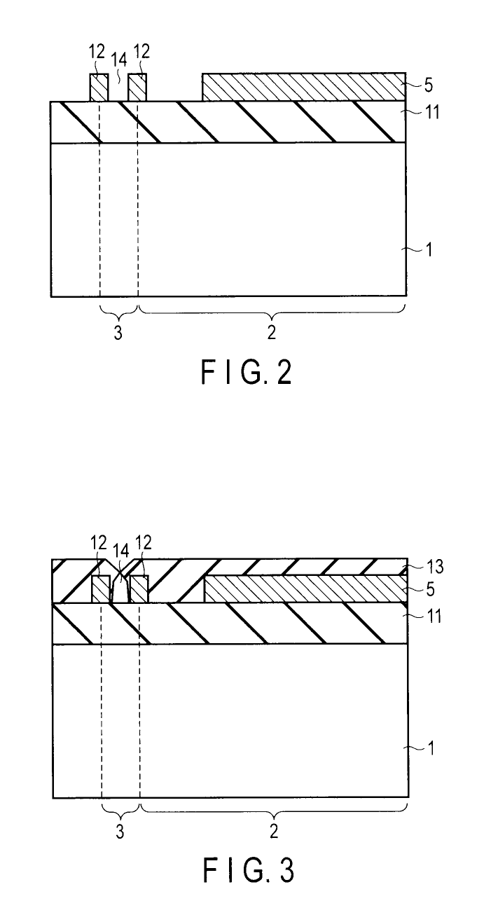

A process for producing the structure of FIGS. 1A and 1B will now be described. FIGS. 2 to 7 are sectional views illustrating steps of the manufacturing method of the semiconductor device of the first embodiment. FIGS. 2 to 7 illustrate the boundary patterns 12 and their peripheries.

The transistor 4 (not shown) is formed on the substrate 1 through ion implantation, film deposition, and patterning of the film by lithography and etching as shown in FIG. 2. The substrate 1 is then covered with the inter-layer film 11. A contact hole for the plug 6 is formed by patterning of the film 11 with lithography and etching. The contact hole is buried with a conductive material. On the inter-layer film 11, a conductive material is then deposited. The conductive material will be processed into the interconnect 5 and the boundary patterns 12. On the conductive material, a mask (not shown) is formed. The mask covers regions above where the interconnect 5 and the boundary patterns 12 will be formed, and has openings in the remaining regions. The conductive material is then patterned by etching through the mask. The conductive material is patterned, in each dicing line 3, into a pair of boundary patterns 12 which extend along the both ends of the corresponding dicing line 3. The area between a pair of boundary patterns 12 serves as the slit 14. The conductive material is also patterned into the interconnect 5 having a predetermined plane shape (geometry) in the chip area 2.

Over the entire upper surface of the structure thus formed so far, the inter-layer film 13 is then deposited as shown in FIG. 3. With this deposition, the exposed portion of the substrate 1 is covered with the inter-layer film 13, and the upper surfaces of the boundary patterns 12 and the interconnect 5 are also covered. This deposition also buries a part of the slit 14 and closes the opening of the slit 14 with the inter-layer film 13. Even though the slit 14 is partly buried, the goal of the embodiment can be attained and advantages to be described later can be obtained so long as it is not entirely buried.

A mask 21 is then formed on the inter-layer film 13 as shown in FIG. 4. The mask 21 has an opening above a region where the plug 17 will be formed in the chip area 2.

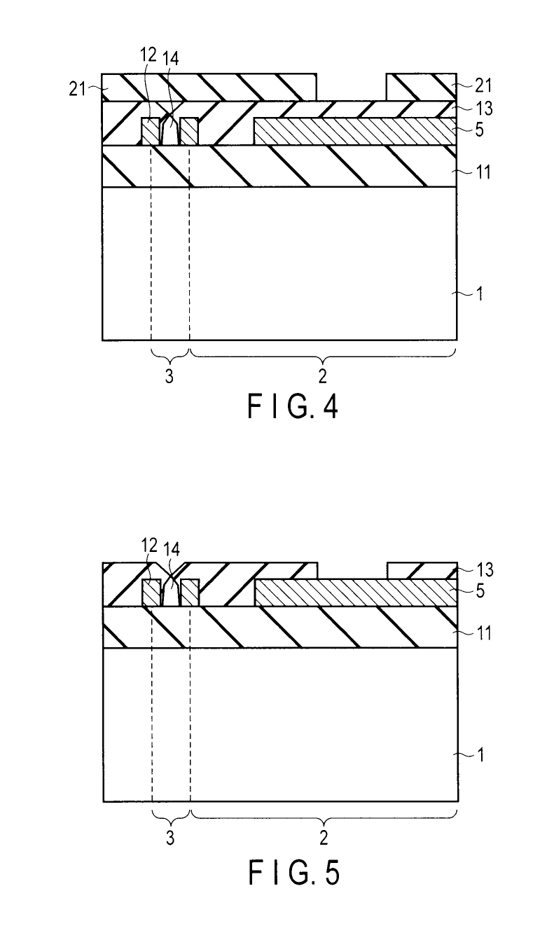

The inter-layer film 13 is then patterned by etching through the mask 21 as shown in FIG. 5. As a result, a via which reaches the interconnect 5 is formed in a region where the plug 17 will be formed in the inter-layer film 13.

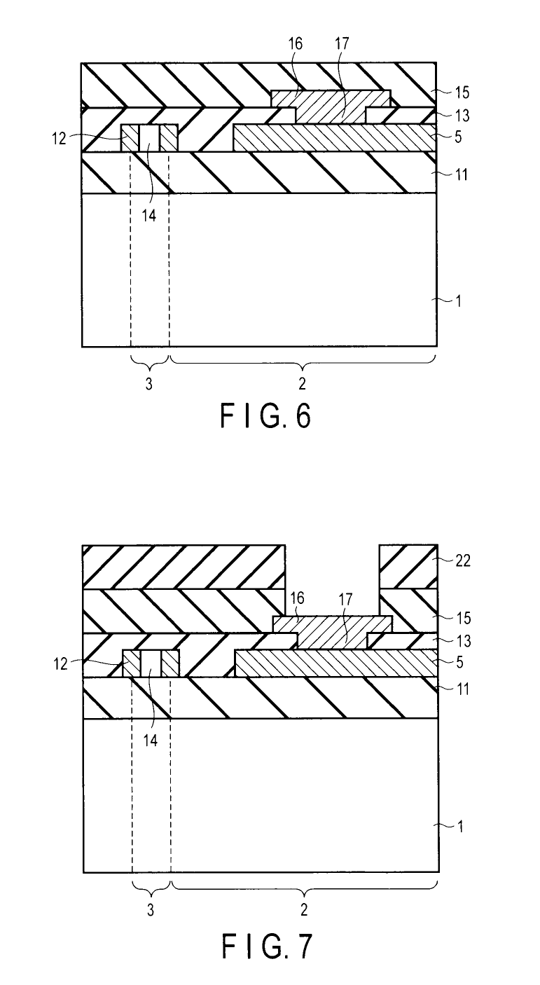

Over the entire upper surface of the structure thus formed so far, a conductive film is then deposited as shown in FIG. 6. This step buries the via for the plug 17 with the conductive film to form the plug 17. The conductive film is then patterned by lithography and etching into a form of the pad 16. The passivation film 15 is then deposited over the entire upper surface of the structure thus formed so far.

A mask 22 is then formed on the passivation film 15 as shown in FIG. 7. The mask 22 has an opening above the pad 16. The passivation film 15 is then patterned by etching through the mask 22 to expose the pad 16. Thus, the structure prior to the laser cutting is formed.

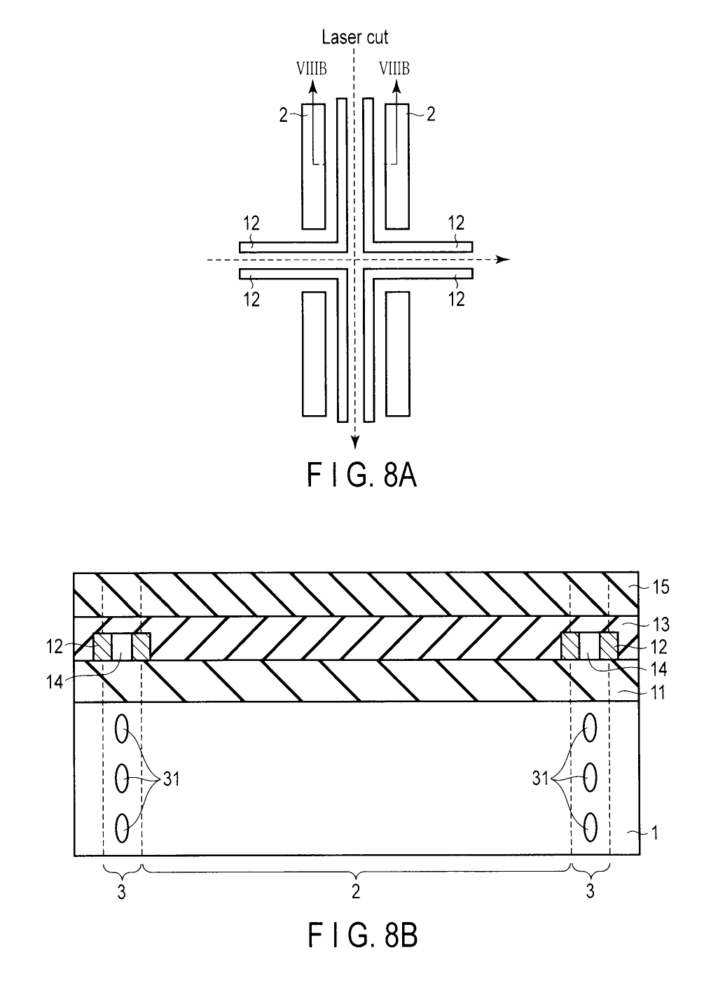

A laser is then irradiated to the substrate 1 as shown in FIGS. 8A and 8B. FIGS. 8A and 8B illustrate the laser cutting step for the semiconductor device in accordance with the first embodiment. FIG. 8A shows a plan view of the substrate, and FIG. 8B the sectional view taken along the VIIIB-VIIIB line in FIG. 8A. A laser is scanned along the dicing lines 3. The laser scan is repeated several times at different depths. In particular, it is first scanned at the deepest depth of the substrate 1, and then scanned at a shallower depth than the first position, and further scanned at a much shallower depth. As a result, laser-cut faults 31 are formed in each dicing line 3 in the substrate 1 as shown in FIG. 8B. The laser-cut faults 31 at different depths are positioned at intervals. Upon the laser irradiation, the slit 13 and the pairs of boundary patterns 12 which sandwich a corresponding slit 3 can serve as marks for recognizing the dicing lines 3.

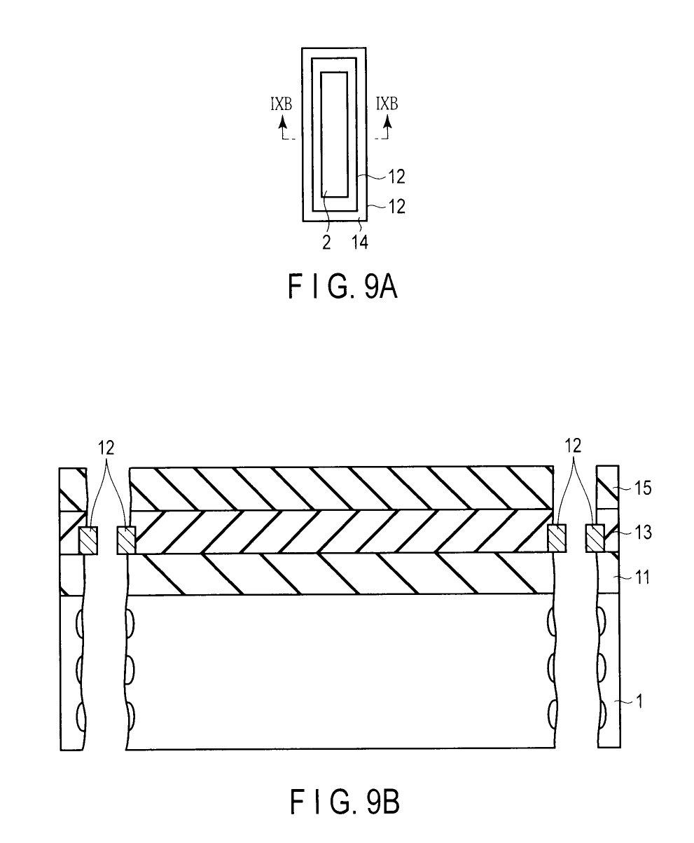

A breaking step is then performed as shown in FIGS. 9A and 9B. FIGS. 9A and 9B illustrate the breaking of the semiconductor device in accordance with the first embodiment. FIG. 9A shows a plan view of the substrate, and FIG. 9B the sectional view taken along the IXB-IXB line in FIG. 9A. The breaking is performed by applying mechanical stress to the substrate 1. In the substrate 1, cracks spread from the laser-cut faults 31, which exhibit decreased intensity, as observed in conventional techniques. Those cracks connect the laser-cut faults 31 and divide chip areas 2 in the substrate 1. In the inter-layer film 13, cracks spread from the slits 14. Thus, with the assistance of the slits 14, a breaking track coincides with each dicing line 3 also in the inter-layer film 13. On the other hand, the breaking track may not necessarily coincide with each dicing line 3 in the passivation film 15 because no slit is provided in the passivation film 15. However, since the crack rightly positioned in the inter-layer film 13 propagates into the passivation film 15 to form a crack there, the undesired shift of the crack from each of the dicing lines 3 in the passivation film 15 is not so large compared with the conventional method. It is a great advantage that the breaking track can be formed in the right position in the inter-layer film 13, which includes electrical components, which are sensitive to the influence of shifts in the breaking track.

As described, the first embodiment involves forming one pair of boundary patterns 12, which form the slit 14 between them, in one dicing line 3 in the inter-layer film 13. Since the breaking starts from the slit 14 in the inter-layer film 13, the breaking track in the inter-layer film 13 coincides with the dicing line 13. In other words, even dicing with the laser can cut up chips at a desired position at least in a region between the substrate 1 and the inter-layer film 13. The breaking track in turn can be prevented from entering the chip area 2 in the inter-layer film 13, which eliminates the necessity for providing a margin for the dicing line width in preparation for such invasion. Therefore, the dicing line 3 can be narrow.

The boundary patterns 12 can also be used for alignment upon dicing. Since the boundary patterns 12 can be seen through a microscope, rough alignment is possible using the boundary patterns 12. This can reduce the time taken for the dicing.

Since the breaking of the chip can be performed more easily than with only laser-cut faults, the number of repetitions of laser irradiations can be decreased. With such decreased number of repetitions, a reduction in manufacturing costs can be expected and a risk of damage to components in the chips which may be caused by the laser can be decreased. In particular, when the semiconductor device is a solid state imaging device, it is an advantage that damage to sensitive components which constitute the solid state imaging device can be avoided.

### Second Embodiment

The second embodiment involves providing boundary patterns and slits also in the passivation film 15.

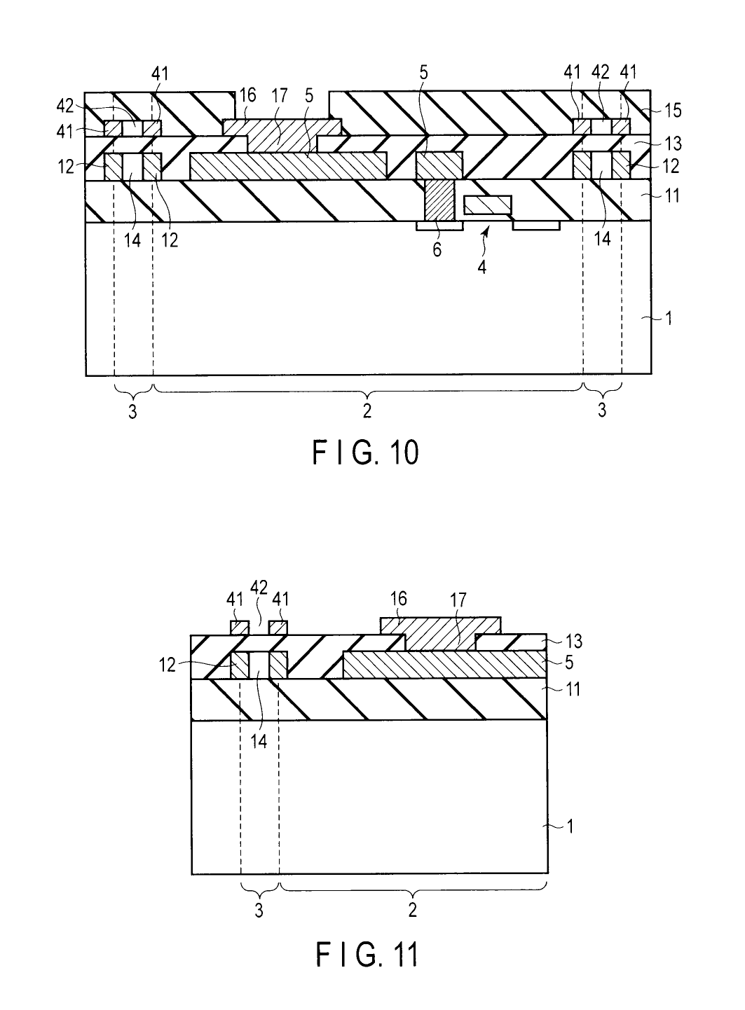

FIG. 10 is a sectional view of a semiconductor device of the second embodiment prior to laser cutting. The boundary patterns 41 are provided in each dicing line 3 in the passivation film 15 as shown in FIG. 10. The boundary patterns 41 comprise the same film as the pad 16, and are patterned by the same process as the pad 16. For this reason, the boundary patterns 41 are typically flush with the pad 16 and have the upper surfaces lower than the upper surface of the passivation film 15. The plane shape of the boundary patterns 41 extends along the both ends of each dicing line 3. The boundary patterns 41 are located above the boundary patterns 12. Similarly to the boundary patterns 12, one boundary pattern 41 surrounds one chip area 2, and a slit 42 is formed between the boundary patterns 41 in one dicing line 3. The slits 42 are located above the slits 14. The boundary patterns 41 make no contribution for electrical signal transmission, and therefore are electrically independent from any components. The boundary pattern 13 may be formed from a material different from the pad 16.

As for a manufacturing process, the same steps are performed as the first embodiment up to formation of the via for plug 17 in the inter-layer film 13 in FIG. 5. FIGS. 11 to 13 are sectional views illustrating steps of a manufacturing method of the semiconductor device of the second embodiment. After the step of FIG. 5A, a conductive film is deposited over the entire upper surface of the structure thus formed so far. This step buries the via for plug 17 with the conductive film to form the plug 17. A mask is then formed on the conductive film. The mask covers regions above where the pad 16 and boundary patterns 41 will be formed.

The conductive film is then patterned by etching through the mask into the pad 16 and the boundary patterns 41 as shown in FIG. 11.

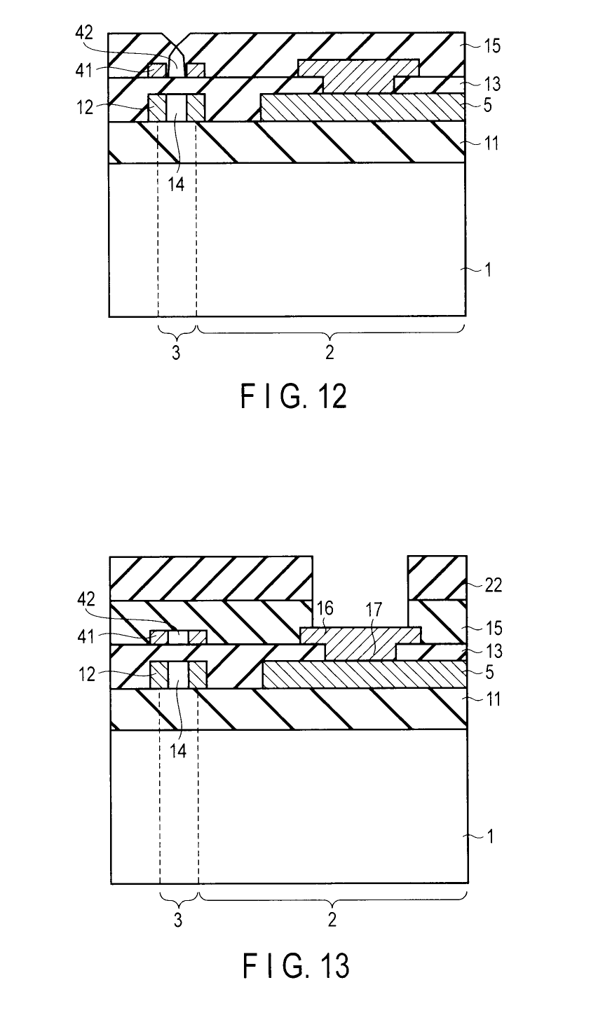

The passivation film 15 is deposited over the entire upper surface of the structure thus formed so far, as shown in FIG. 12. This deposition buries a part of the slit 42 and closes the opening of the slit 42 with the passivation film 15. Even though the slit 42 is partly buried, the goal of the embodiment can be attained and advantages to be described later can be obtained so long as it is not entirely buried.

A mask 22 is then formed on the passivation film 15 as shown in FIG. 13. The mask 22 has an opening above the pad 16. The passivation film 15 is then patterned by etching through the mask 22 to expose the pad 16. Thus, the structure prior to the laser cutting is formed.

The laser cutting is the same as that of the first embodiment. It is however different from the first embodiment in that breaking in the passivation film 15 starts from the slit 42. Features not described above are all the same as in the first embodiment.

As described, the second embodiment involves forming one pair of boundary patterns 12, which form the slit 14 between them, in one dicing line 3 in the inter-layer film 13. This provides the same advantages as the first embodiment. In addition, the second embodiment also involves forming one pair of boundary patterns 41, which form the slit 42 between them, in one dicing line 3 in the passivation film 15. Since the breaking in the passivation film 15 starts from the slit 42, the breaking track extends along the dicing line 3 in the passivation film 15 as well as in the inter-layer film 13. Therefore, the breaking can be performed with improved accuracy in a region between the substrate 1 and the passivation film 15.

### Third Embodiment

The third embodiment involves forming a slit, which penetrates through the inter-layer film 13 and the passivation film 15.

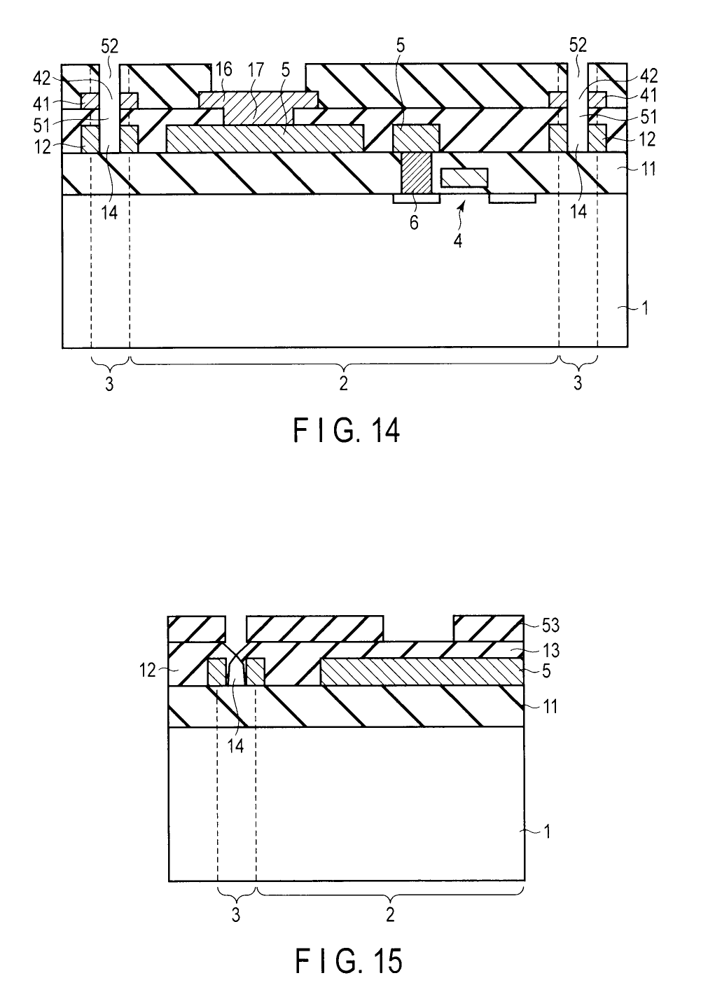

FIG. 14 is a sectional view of a semiconductor device of the third embodiment prior to laser cutting. Slits 51 are formed above the slits 14 in the inter-layer film 13 as shown in FIG. 14. Each slit 51 has a plane shape which extends along the corresponding slits 14 and 42, and its cross-sectional structure connects slits 14 and slits 42.

Slits 52 are formed above the slits 42 in the passivation film 15. Each slit 52 has a plane shape which extends along the corresponding slit 42, and its cross-sectional structure extends between the upper surface of the passivation film 15 and the corresponding slit 42. Therefore, a set of slits 12, 42, 51, and 52 form a slit, which penetrates from the surface of the passivation film 15 to the surface of the substrate 1.

A manufacturing process is similar to the second embodiment. FIGS. 15 to 19 are sectional views illustrating steps of a manufacturing method of the semiconductor device of the third embodiment. The same steps are performed as the first embodiment up to FIG. 3. A mask 53 is then formed on the inter-layer film 13 as shown in FIG. 15. The mask 53 has openings above regions where the plug 17 and the slit 14 will be formed.

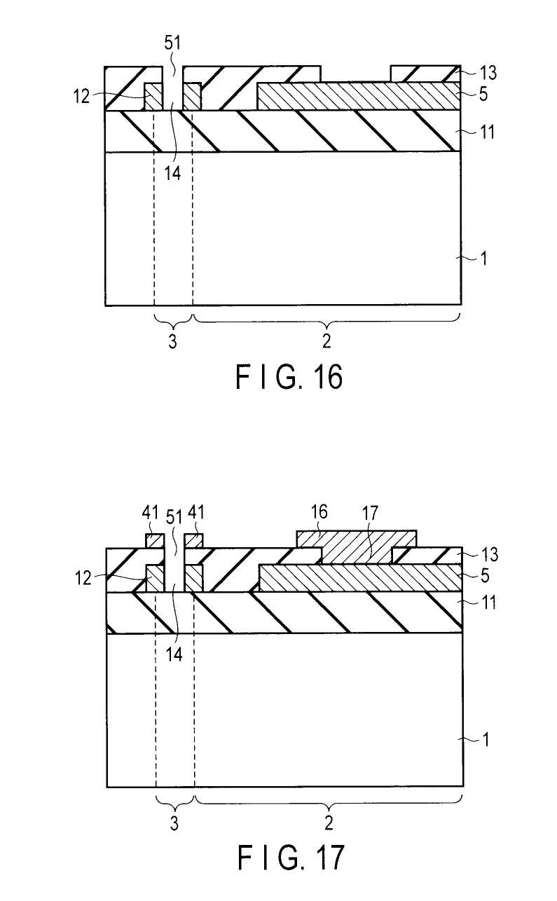

The inter-layer film 13 is then patterned by etching through the mask 53 as shown in FIG. 16. As a result, in the inter-layer film 13, a via which reaches the interconnect 5 is formed in the region where the plug 17 will be formed and the slit 51 is also formed. This etching also removes the inter-layer film 13 which buries a part of the slit 14 and closes the opening of the slit 14.

A conductive film is then deposited over the entire upper surface of the structure thus formed so far, as shown in FIG. 17. This deposition buries the via for plug 17 with the conductive film to form the plug 17. A mask is then formed on this conductive film. The mask covers regions above where the pad 16 and the boundary patterns 41 will be formed. The conductive film is then patterned by etching through the mask into the pad 16 and the boundary patterns 41.

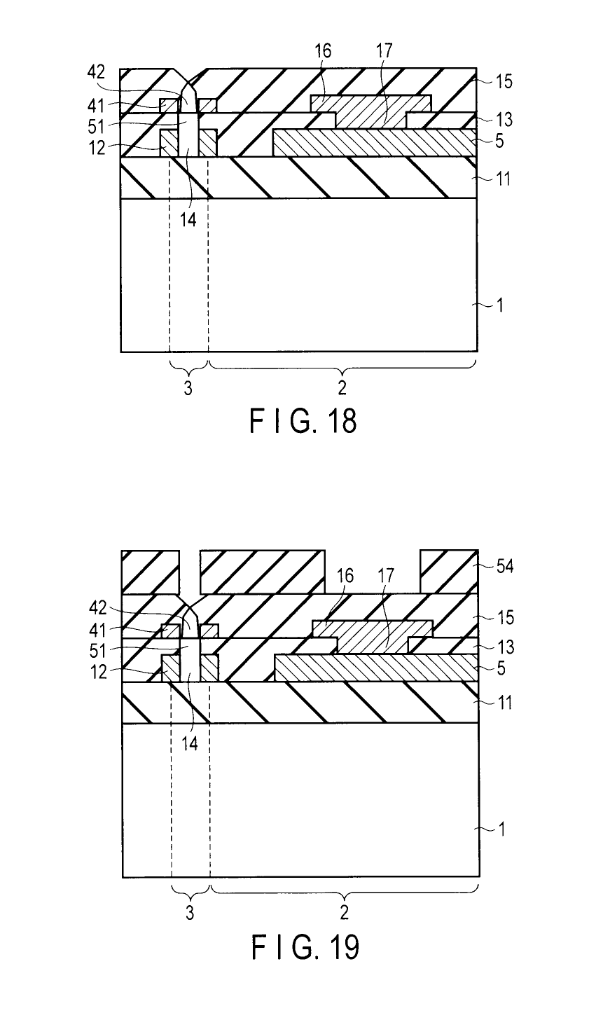

The passivation film 15 is then deposited over the entire upper surface of the structure thus formed so far, as shown in FIG. 18. Regions above regions between the pair of boundary patterns 41 are closed by the passivation film 15.

A mask 54 is then formed on the passivation film 15 as shown in FIG. 19. The mask 54 has openings above where the pad 16 and the slits 52 will be formed. The passivation film 15 is patterned and the slit 52 is formed by etching through the mask. This etching also removes the passivation film 15 which buries the part of the slit 42 and closes the opening of the slit 42. Thus, the structure prior to the laser cutting is formed.

The laser cutting is the same as in the first embodiment. However, the inter-layer film 13 and the passivation film 15 were already divided into separate chip areas 2 at the time of breaking. Therefore, the substrate 1 is the only target of the breaking. Features not described above are all the same as in the first and second embodiments.

As described, the third embodiment involves forming one pair of boundary patterns 12, which form the slit 14 between them, in one dicing line 3 in the inter-layer film 13. One pair of boundary patterns 41, which form the slit 42 between them, are also formed in one dicing line 3 in the passivation film 15 as in the second embodiment. Therefore, the same advantages as in the first and second embodiments are obtained. In addition, the third embodiment also involves forming a slit from the slits 51 and 52, which penetrates through the inter-layer film 13 and the passivation film 15. This means that the inter-layer film 13 and the passivation film 15 are already divided into separate chip areas 2 at the time of the breaking. For this reason, the breaking track in the inter-layer film 13 and the passivation film 15 can be prevented from entering the chip area 2. Therefore, the breaking can be performed with improved accuracy in a region between the substrate 1 and the passivation film 15.

### Fourth Embodiment

The fourth embodiment is performed additionally to the first to third embodiments, and involves forming a slot in a substrate along each dicing line.

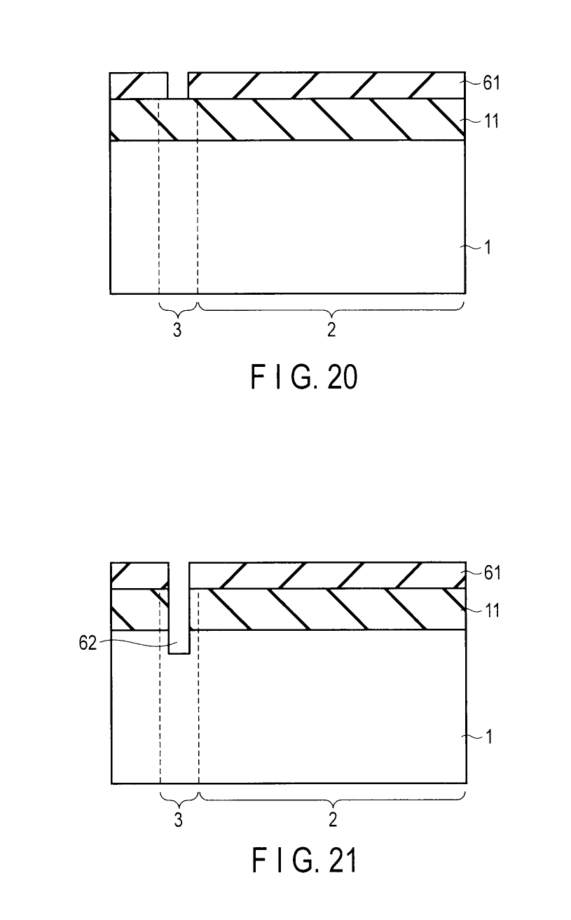

FIGS. 20 and 21 are sectional views illustrating steps of a manufacturing method of a semiconductor device of the fourth embodiment. A transistor (not shown) is formed as described with reference to FIG. 2 of the first embodiment as shown in FIG. 20. The upper surface of the substrate 1 is then covered with the inter-layer film 11. A mask 61 is then formed on the inter-layer film 11. The mask 61 has openings above where the plug 6 will be formed in the chip area 2 and above the dicing line 3.

The contact hole for the plug 6 is formed and a slot 62 is formed in the surface area of the substrate 1 in the dicing line 3 by etching through the mask 61 as shown in FIG. 21. The slot 62 reaches a depth a little shallower than where the shallowest laser-cut fault will be located, and has a plane shape extending along the dicing line 3. Alternatively, the slot 62 may be formed by etching which forms trenches for element isolation insulation films in the substrate 1.

As the following steps, steps of one or more of the first to third embodiments are performed. The laser cutting and breaking are also performed as described for the first embodiment. The breaking of the substrate 1, however, starts from the slot 62 as well as the laser-cut faults. Features not described above are all the same as in the first and third embodiments.

As described above, the fourth embodiment involves forming the slot 62 in the surface region of the substrate 1 in one dicing line 3. The slot 62 serves as the starting point of the breaking on the substrate 1 as well as the laser-cut faults 31. For this reason, the breaking can be performed for the substrate 1 with improved accuracy. This eliminates the necessity for providing the margin for the dicing line width, and can narrow the dicing line 3. Since the fourth embodiment is combined with one of the first to third embodiments, the same advantages as the combined embodiment can also be obtained.

### Fifth Embodiment

The fifth embodiment is performed additionally to the first to third embodiments, and involves forming a slot in a conductive material on the substrate 1 along each dicing line.

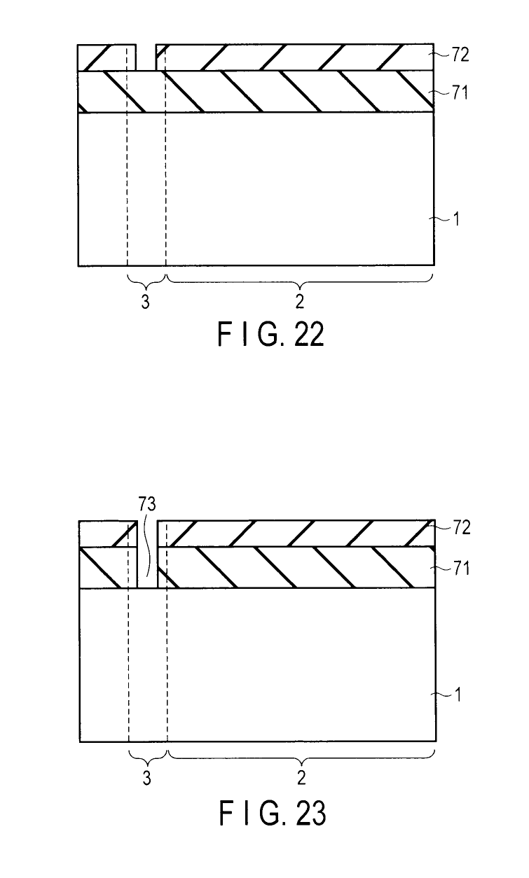

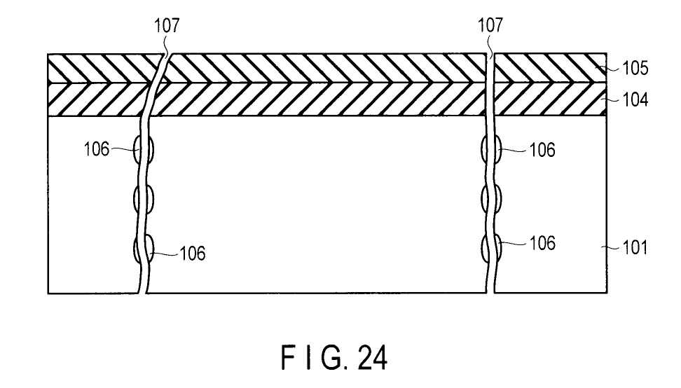

FIGS. 22 and 23 are sectional views illustrating steps of a manufacturing method of a semiconductor device according to the fifth embodiment. A conductive material 71 is deposited on the upper surface of the substrate 1 as shown in FIG. 22. The conductive material 71 may be of polysilicon and will be patterned into the gate electrode. A mask 72 is then formed on the conductive material 71. The mask 72 has an opening above the dicing line 3 and covers a region above where the gate electrode will be formed. Etching through the mask 72 is then performed to form a slit 73 in the conductive material 71 in the dicing line 3 and the gate electrode as shown in FIG. 23.

As the following steps, steps of one or more of the first to fourth embodiments are performed. The laser cutting and breaking are also performed as described for the first embodiment. Features not described above are all the same as in the first and third embodiments.

As described above, the fifth embodiment is combined with one or more of the first to fourth embodiments. Therefore, the same advantage as the combined embodiment can be obtained.

When mechanical stress is applied to the substrate 101 after the laser cutting, a breaking track may deviate from a corresponding dicing line in an inter-layer film 104 and a passivation film 105 as shown in FIG. 24.

This is because the laser-cut faults are not formed in the inter-layer film 104 or the passivation film 105 and the breaking in them is only performed with the mechanical stress but without assistance of laser-cut faults. With the deviation of the breaking track 107 from a desired position in the inter-layer film 104 and the passivation film 105, interconnects and plugs may be deformed to result in loss of electrical connection. One possible measure to avoid such intrusion by the breaking track 107 into a chip area is to widen the dicing line. This measure enables the widened margin to serve as an area used as a buffer to prevent the breaking track which has entered the chip area from reaching electrical components. This technique is, however, counter to the request to reduce a dicing line width. Thus, there is a need for a countermeasure other than widening the dicing line to provide the margin.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate which includes a first chip area and a second chip area;
an insulation film over the substrate;
an electrical circuit in the first chip area and electrically independent from any component in another chip area, the electrical circuit including an electrical element and an interconnect on the substrate and in the insulation film; and
boundary patterns in the insulation film between the first and second chip areas and electrically independent from the electrical circuit, the boundary patterns having a gap therebetween, one of the boundary patterns surrounding the first chip area.

2. The device of claim 1, wherein
the boundary patterns derive from the same material as the interconnect.

3. The device of claim 1, wherein
one of the boundary patterns surrounds the second chip area.

4. The device of claim 1, wherein
the electrical circuit includes a transistor,
the insulation film includes a first insulation film over a surface of the substrate and a second insulation film over the first insulation film; and
the boundary patterns are located in the second insulation film.

5. The device of claim 4, wherein
the boundary patterns derive from the same material as the interconnect; and
the interconnect is located in the second insulation film.

6. The device of claim 1, further comprising second boundary patterns which are located above the boundary patterns in the insulation film, are electrically independent from the electrical circuit, and have a second gap between the first and second chip areas, and one of which surrounds the first chip area.

7. The device of claim 6, wherein
the electrical circuit includes a transistor,
the insulation film includes a first insulation film over a surface of the substrate and the transistor, a second insulation film over the first insulation film, and a third insulation film over the second insulation film,
the device further comprises a conductive pad electrically connected to the electrical circuit and exposed by an opening in the third insulation film,
the boundary patterns are located in the second insulation film, and
the second boundary patterns are located in the third insulation film.

8. The device of claim 6, wherein
the boundary patterns derive from the same material as the interconnect,
the interconnect is located in the second insulation film,
the second boundary patterns derive from the same material as the pad, and
the pad is located in the third insulation film.

9. The device of claim 6, further comprising a hole which connects the gap and the second gap and penetrates through the insulation film.

10. The device of claim 1, further comprising a hole which penetrates through the insulation film between the first and second chip areas to inside of the substrate.

11. A method of manufacturing a semiconductor device comprising:
forming an electrical element in a first chip area on a semiconductor substrate, the element electrically independent from any component in another chip area;
etching a conductive film above the substrate to form boundary patterns, the boundary patterns electrically independent from an interconnect electrically connected to the electrical element, the boundary patterns forming a gap between the first chip area and a second chip area adjacent the first chip area; and
covering the interconnect and the boundary patterns with an insulation film without burying the gap entirely.

12. The method of claim 11, further comprising:
irradiating the substrate below the gap with a laser; and
dividing the first chip area and the second chip area.

13. The method of claim 11, wherein
the etching of the conductive film includes forming the interconnect and the boundary patterns.

14. The method of claim 11, wherein
the electrical element includes a transistor on the substrate,
the method further comprises forming a second insulation film over the substrate and the transistor,
the conductive film is located on the second insulation film, and
the insulation film is located on the second insulation film.

15. The method of claim 11, further comprising:
forming a second conductive film on the insulation film;
etching the second conductive film to form second boundary patterns electrically independent from the electrical element, the second boundary patterns forming a second gap between the first and second chip areas;
covering the second boundary patterns with a second insulation film without burying the second gap entirely.

16. The method of claim 15, wherein
the etching of the second conductive film includes forming a conductive pad electrically connected to the electrical element, and the second boundary patterns.

17. The method of claim 15, further comprising, after covering the second boundary patterns, etching the second insulation film from above the second gap to form a hole which includes the second gap and penetrates through the second insulation film and the insulation film.

18. The method of claim 11, wherein
the electrical element includes a transistor on the substrate,
the method further comprises:
forming a second insulation film over the substrate and the transistor; and
etching the second insulation film to form a hole which penetrates through the second insulation film between the first and second chip areas to inside of the substrate.
